(19) United States
(12) Patent Application Publication
(10) Pub. No.: US 2023/0360838 A1
(43) Pub. Date: Nov. 9, 2023

(54) CIRCUIT COMPONENT AND SEMICONDUCTOR DEVICE

(71) Applicant: ROHM CO., LTD., Kyoto-shi, Kyoto (JP)

(72) Inventors: Tatsuya MIYAZAKI, Kyoto-shi, Kyoto (JP); Yuta OKAWAUCHI, Kyoto-shi, Kyoto (JP)

(21) Appl. No.: 18/246,501

(22) PCT Filed: Sep. 6, 2021
(86) PCT No.: PCT/JP2021/032596

§ 371 Date: Mar. 23, 2023

(30) Foreign Application Priority Data
Oct. 5, 2020 (JP) 2020-168339

(51) Int. Cl. H01F 27/255; H01L 25/16; H01F 37/00; H01F 27/28

(52) U.S. Cl. CPC H01F 27/255; H01L 25/16; H01F 37/00; H01F 27/2804; H01F 2027/2809

(57) ABSTRACT

A circuit component includes a resin composite body and a conductor. The resin composite body is composed of a resin material and a plurality of magnetic particles contained in the resin material. The conductor is formed on the surface of the resin composite body. The magnetic particles are dispersed in the resin material.

### TECHNICAL FIELD

The present disclosure relates to a circuit component and a semiconductor device.

### BACKGROUND ART

Conventionally, circuit components are incorporated in various electronic devices such as industrial equipment, home appliances, information terminals, and automotive equipment. Examples of such circuit components include magnetic components such as inductors and transformers. An example of a conventional inductor component is disclosed in Patent Document 1, for example. The inductor component disclosed in Patent Document 1 has insulating layers and conductor patterns. The insulating layers and the conductor patterns are alternately stacked. The conductor patterns have a spiral shape, for example, and a magnetic field is generated when a current flows through the conductor patterns.

### PRIOR ART DOCUMENT

### Patent Document

Patent Document: JP-A-2005-109097

### SUMMARY OF THE INVENTION

### Problem to be Solved by the Invention

For improved performance of electronic devices incorporating circuit components, the circuit components are required to have improved characteristics. For example, when the circuit component is a magnetic component, the inductance value needs to be improved. Some magnetic components use a rod-shaped or annular magnetic core (iron core) to improve the inductance value. However, using a magnetic core generates core loss (iron loss) due to the magnetic properties of the magnetic core.

In light of the above circumstances, an object of the present disclosure is to provide a circuit component capable of reducing iron loss while improving the inductance value. Another object of the present disclosure is to provide a semiconductor device incorporating such a circuit component.

### Means to Solve the Problem

A circuit component provided according to a first aspect of the present disclosure includes: a resin composite body including a resin material containing a plurality of magnetic particles; and a conductor formed on a surface of the resin composite body, and is characterized in that the plurality of magnetic particles are dispersed in the resin material.

A semiconductor device, which is provided according to a second aspect of the present disclosure, includes a circuit component provided according to the first aspect and a transistor electrically connected to the circuit component.

### Advantages of the Invention

The circuit component according to the present disclosure achieves both improvement of the inductance value and reduction of iron loss. The semiconductor device according to the present disclosure can improve the performance, because it incorporates a circuit component that achieves both improvement of the inductance value and reduction of iron loss.

### BRIEF DESCRIPTION OF THE DRAWINGS

FIG. 1 is a perspective view of a circuit component according to a first embodiment;

FIG. 2 is a plan view of the circuit component according to the first embodiment;

FIG. 3 is a sectional view taken along line III-III in FIG. 2;

FIG. 4 is an enlarged sectional view of a portion of FIG. 3, schematically illustrating the resin composite body 2;

FIG. 5 is a plan view showing a step of a manufacturing method of the circuit component according to the first embodiment;

FIG. 6 is a sectional view taken along line VI-VI in FIG. 5;

FIG. 7 is a plan view showing a step of a manufacturing method of the circuit component according to the first embodiment;

FIG. 8 is a sectional view taken along line VIII-VIII in FIG. 7;

FIG. 9 is a plan view showing a step of a manufacturing method of the circuit component according to the first embodiment;

FIG. 10 is a plan view showing a step of a manufacturing method of the circuit component according to the first embodiment;

FIG. 11 is a front view of a semiconductor device including the circuit component according to the first embodiment;

FIG. 12 is a plan view of a circuit component according to a variation of the first embodiment;

FIG. 13 is a sectional view of a circuit component according to a variation of the first embodiment;

FIG. 14 is a sectional view of a circuit component according to a variation of the first embodiment;

FIG. 15 is a sectional view of a circuit component according to a variation of the first embodiment;

FIG. 16 is a perspective view of a circuit component according to a second embodiment;

FIG. 17 is a plan view of a circuit component according to a second embodiment; and

FIG. 18 is a sectional view taken along line XVIII-XVIII in FIG. 17.

### MODE FOR CARRYING OUT THE INVENTION

Preferred embodiments of a circuit component and a semiconductor device according to the present disclosure are described below with reference to the drawings. In the following description, the same or similar elements are denoted by the same reference signs, and descriptions thereof are omitted.

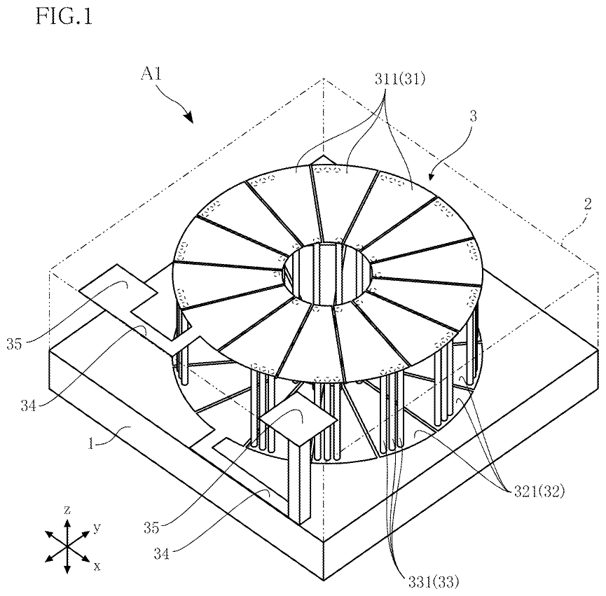

A circuit component A1 according to a first embodiment is described below with reference to FIGS. 1 to 4. As shown in these figures, the circuit component A1 includes a support substrate, a resin composite body 2 and a conductor 3.

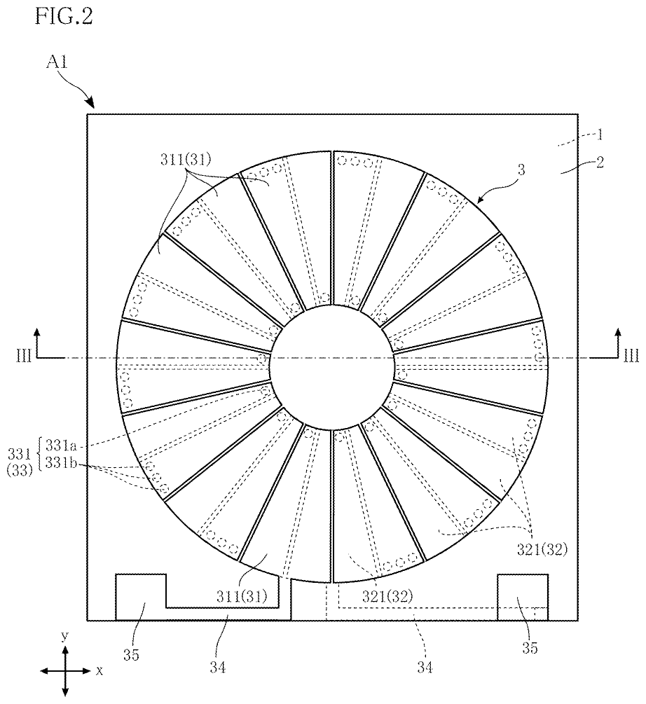

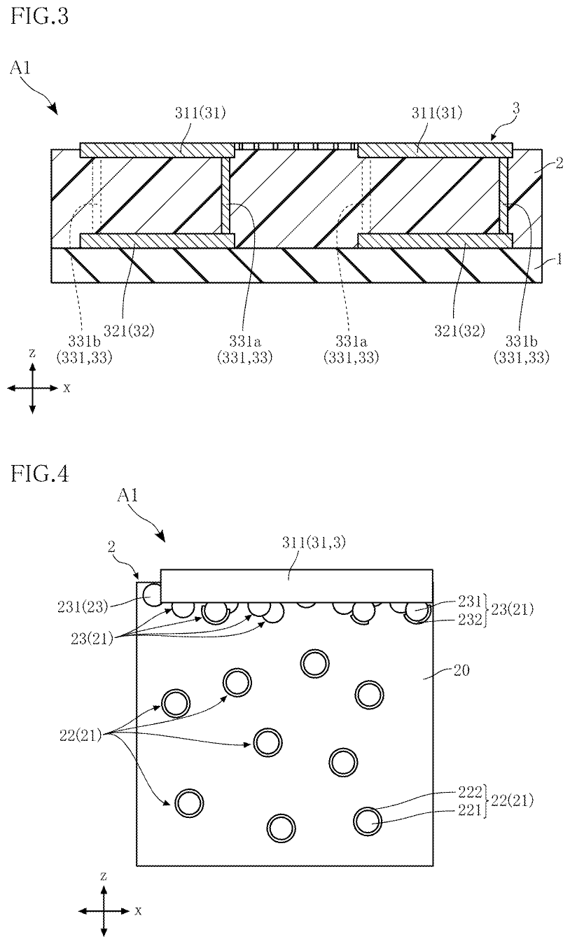

FIG. 1 is a perspective view of the circuit component A1. In FIG. 1, the resin composite body 2 is shown by imaginary lines (two-dot chain lines). FIG. 2 is a plan view of the circuit component A1. FIG. 3 is a sectional view taken along line III-III in FIG. 2. FIG. 4 is an enlarged sectional view of a portion of FIG. 3, schematically illustrating the resin composite body 2.

For convenience of description, reference will be made to three mutually orthogonal directions, i.e., the x direction, the y direction and the z direction. The z direction is the thickness direction of the circuit component A1. The x direction is the horizontal direction in a plan view (see FIG. 2) of the circuit component A1. The y direction is the vertical direction in a plan view (see FIG. 2) of the circuit component A1. In the description below, “plan view” means a view seen in the z direction.

The circuit component A1 is a magnetic component that produces inductance from the current flowing in the conductor 3. The present embodiment describes an example in which the circuit component A1 is an inductor. The size of the circuit component A1 may vary. In one example, each of the dimension in the x direction and the dimension in the y direction is about 1 to 10 mm.

The support substrate 1 supports the resin composite body 2 and the conductor 3. The support substrate 1 is rectangular in plan view, for example. The support substrate 1 is an insulating substrate, such as a silicon substrate, a glass epoxy substrate, a resin substrate, or a ceramic substrate.

The resin composite body 2 is made of a resin material 20 containing a plurality of magnetic particles 21. The volume content of the magnetic particles 21 in the resin composite body 2 is not less than 60% and not more than 90%, for example. The relative magnetic permeability of the resin composite body 2, i.e., the magnetic permeability of the composite of the resin material 20 and the magnetic particles 21 is 10 or greater, for example. The relative magnetic permeability of the resin composite body 2 is not limited to 10 or greater. However, the relative magnetic permeability of 10 or greater is preferable for making the circuit component A1 have an inductance suitable for practical use. The resin composite body 2 is rectangular in plan view. The resin material 20 is, for example, a thermosetting resin, such as epoxy resin or phenolic resin. The resin composite body 2 is formed on the support substrate 1. The plurality of magnetic particles 21 include a plurality of first particles 22 and a plurality of second particles 23.

As shown in FIG. 4, the plurality of first particles 22 are dispersed in the resin material 20. That is, the plurality of first particles 22 are present in the resin material 20 while being spaced apart from each other. The plurality of first particles 22 each include a first core 221 and an insulating coating film 222. As an example, the separation distance of any two of the first particles 22 is larger than the diameter of each first particle 22 (or first core 221), but the present disclosure is not limited to this. For example, any two first particles 22 may only be required to be present in the resin material 20 such that their insulating coating films 222 do not come into contact with each other. In that case, the separation distance between the two first particles 22 may be smaller than the diameter (or radius) of each of these first particles 22 (or the first cores 221).

The first cores 221 are made of metallic magnetic powder. As the metallic magnetic powder, materials containing a metallic element that exhibits ferromagnetism by itself are preferably used, examples of which include materials containing one or more elements selected from Fe, Co and Ni (i.e., containing Fe or Co or Ni, or their alloys or compounds). The insulating coating films 222 cover the entire surfaces of the first cores 221, respectively. The material of the insulating coating films 222 is the oxide of the first cores 221, for example. The material of the insulating coating films 222 may not be the oxide of the first cores 221 but may be silicon oxide, silicon nitride, or an insulating resin, for example. With the insulating coating films 222 covering the entire surfaces of the first cores 221, each first particle 22 is insulating. The particle size of the first cores 221 is, for example, about several hundred nanometers to several tens of micrometers, and the film thickness of the insulating coating films 222 is, for example, about several nanometers to several tens of nanometers. Each first particle 22 may be made insulating by the entire particle being made of an oxide-based magnetic material such as ferrite, rather than by the entire surface of the first core 221 being covered with the insulating coating film 222.

Each of the second particles 23 is in contact with the conductor 3 within the resin material 20. The plurality of second particles 23 each include a second core 231.

The second cores 231 are made of metallic magnetic powder. This metallic magnetic powder is the same as the metallic magnetic powder of the first cores 221. That is, as the metallic magnetic powder of the second cores 231, materials containing a metallic element that exhibits ferromagnetism by itself are preferably used, examples of which include materials containing one or more elements selected from Fe, Co, and Ni. The particle size of the second cores 231 is the same as that of the first cores 221.

As shown in FIG. 4, the plurality of second particles 23 may have insulating coating films 232 formed so as to expose at least portions of the surfaces of the second cores 231. The material of the insulating coating films 232 is the oxide of the second cores 231, for example. The material of the insulating coating films 222 and the material of the insulating coating films 232 are the same. The material of the insulating coating films 232 may not be the oxide of the second cores 231 but may be silicon oxide, silicon nitride, or an insulating resin, for example. Such second particles 23 that have insulating coating films 232 are in contact with the conductor 3 at their portions exposed from the insulating coating films 232. The film thickness of the insulating coating films 232 is the same as that of the insulating coating films 222.

The conductor 3 serves as the functional center of the circuit component A1. In the circuit component A1, the conductor 3 forms the inductor portion. In the present embodiment, the conductor 3 is wound into a toroidal shape. As shown in FIG. 2, the conductor 3 is annular in plan view. The material of the conductor 3 may be any electrically conductive material, but is preferably Cu or a Cu alloy in view of the wiring resistance and the forming method (i.e., at least a portion being formed by plating). The conductor 3 includes a first conductor layer 31, a second conductor layer 32, a conducting portion 33, connecting portions 34, and a pair of terminals 35.

The first conductor layer 31 and the second conductor layer 32 face each other, with the resin composite body 2 interposed therebetween. In the example shown in FIG. 3, the first conductor layer 31 and the second conductor layer 32 are disposed on opposite surfaces of the resin composite body 2 in the z direction. The first conductor layer 31 and the second conductor layer 32 are plating layers, for example. The first conductor layer 31 and the second conductor layer 32 are each formed into an annular pattern in plan view.

The first conductor layer 31 is separated into a plurality of first conductor portions 311. The second conductor layer 32 is separated into a plurality of second conductor portions 321. The first conductor portions 311 and the second conductor portions 321 are arranged such that a part of each first conductor portion overlaps with a part of a second conductor portion in plan view. In the example shown in FIG. 2, the first conductor portions 311 and the second conductor portions 321 are displaced from each other by half a section in the toroidal direction. Each of the first conductor portions 311 and second conductor portions 321 is tapered such that its width increases radially outward and decreases radially inward in plan view. Each of the first conductor portions 311 and second conductor portions 321 is generally fan-shaped. The second particles 23 are in contact with either the first conductor portions 311 (first conductor layer 31) or the second conductor portions 321 (second conductor layer 32). One of the first conductor portions 311 and one of the second conductor portions 321 are connected to respective connecting portions 34.

The conducting portion 33 connects the first conductor layer 31 and the second conductor layer 32 to each other. The conducting portion 33 penetrates the resin composite body 2 in the z direction. The conducting portion 33 includes a plurality of vias 331.

Each of the vias 331 penetrates the resin composite body 2 in the z direction and electrically connects one of the first conductor portions 311 and one of the second conductor portions 321. Each via 331 is formed in an area in which one of the first conductor portions 311 and one of the second conductor portions 321 overlap with each other in plan view. Each via 331 is connected to one of the first conductor portions 311 at one end in the z direction and connected to one of the second conductor portions 321 at the other end in the z direction.

The plurality of vias 331 include a plurality of inner vias 331a and a plurality of outer vias 331b. Each of the inner vias 331a connects one of the first conductor portions 311 and one of the second conductor portions 321, on the radially inner side of the conductor 3. The outer vias 331b connect each of the first conductor portions 311 and a relevant one of the second conductor portions 321, on the radially outer side of the conductor 3.

In plan view, each first conductor portion 311 overlaps with two conductor portions 321 adjacent to each other in the circumferential direction (toroidal direction) of the conductor 3, and an inner via 331a is disposed in an area in which the first conductor portion 311 overlaps with one of the second conductor portions 321, whereas an outer via(s) 331b is disposed in an area in which the first conductor portion 311 overlaps with the other one of the second conductor portions 321. Thus, the inner via 331a and the outer via 331b connecting to a given first conductor portion 311 are connected to two different second conductor portions 321 adjacent to each other in the toroidal direction of the conductor 3. With such a configuration, a current flows from a first conductor portion 311 to another first conductor portion 311 next to it in the toroidal direction through an inner via 331a, a second conductor portion 321 and an outer via 331b in that order. In the example shown in FIG. 2, a current flows radially inward of the conductor 3 when flowing in each first conductor portion 311 and flows radially outward of the conductor 3 when flowing in each second conductor portion 321. In this way, the current path circles in the toroidal direction (clockwise in the example shown in FIG. 2), forming a toroidal current path extending from the first conductor portion 311 connected to one connecting portion 34 to the second conductor portion 321 connected to the other connecting portion 34.

The conductor 3 is designed such that a predetermined self-inductance is provided by the first conductor layer 31, the second conductor layer 32 and the conducting portion 33. Preferably, the self-inductance is 10 nH or greater, for example.

The connecting portions 34 connect the first conductor layer 31 and the second conductor layer 32 to the paired terminals 35, respectively. The connecting portions 34 include one connecting the first conductor layer 31 and one of the paired terminals 35, and another one connecting the second conductor layer 32 and the other one of the paired terminals 35.

The pair of terminals 35 are the input and output terminals for current in the circuit component A1. One of the terminals 35 connects to one of the first conductor portions 311 through a connecting portion 34. The other one of the terminals 35 connects to one of the second conductor portions 321 through a connecting portion 34. The current input to one of the terminals 35 is output from the other terminal 35. In the example shown in FIGS. 1 and 2, the terminals 35 are disposed on the upper surface (one side in the z direction) of the resin composite body 2. The arrangement of the terminals 35 may vary as appropriate.

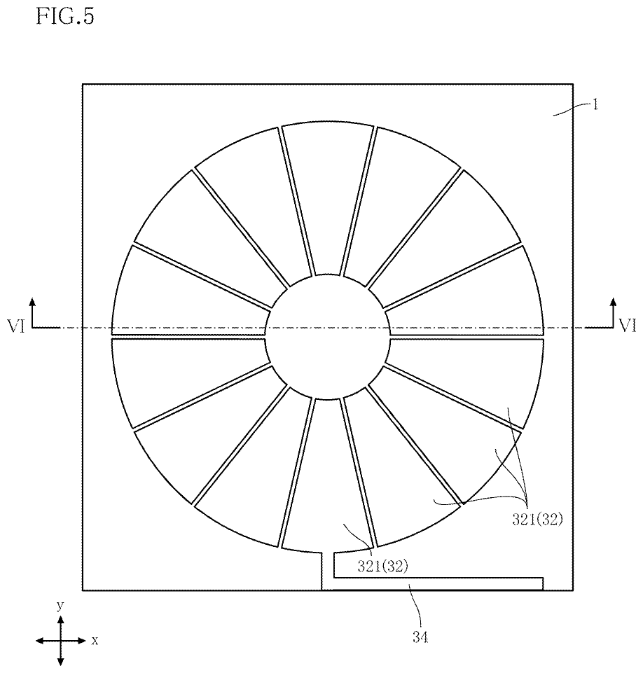

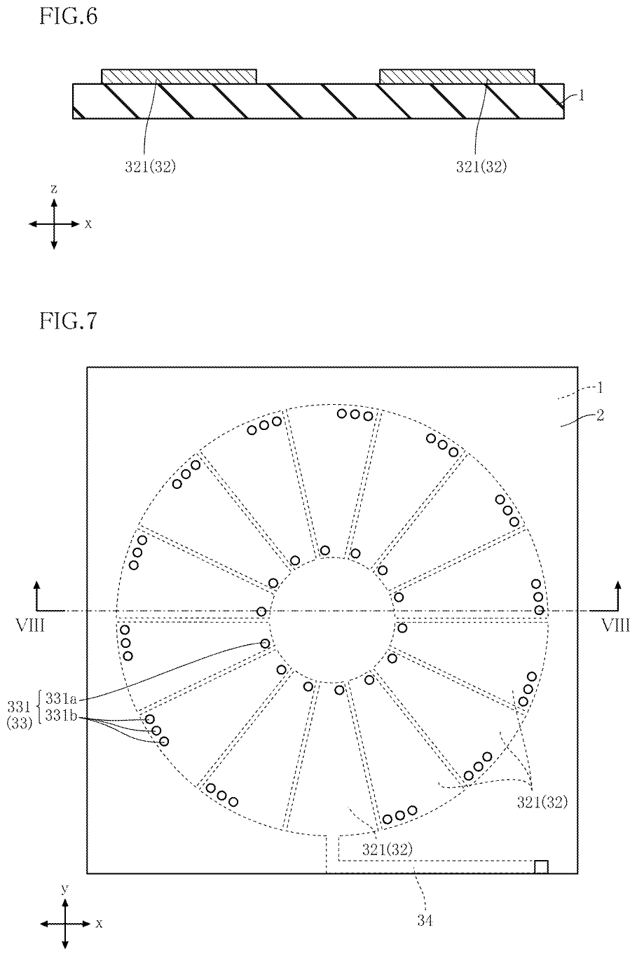

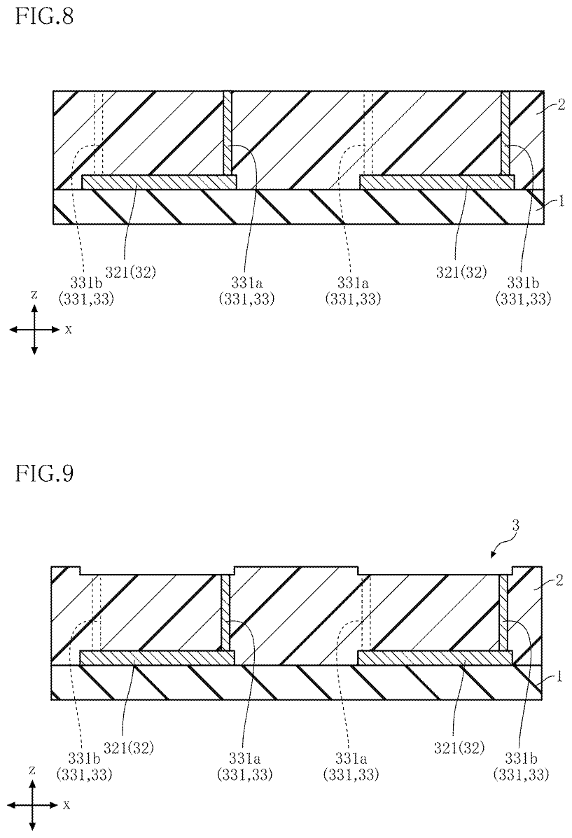

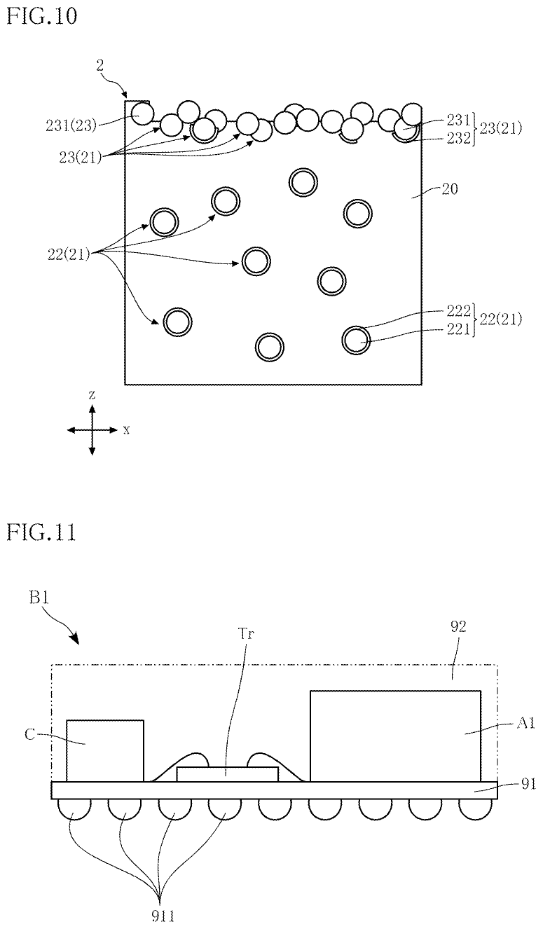

Next, a method for manufacturing the circuit component A1 is described below with reference to FIGS. 5 to 10. FIGS. 5 to 10 each show a step of the manufacturing method of the circuit component A1. FIGS. 5 and 7 are plan views. FIGS. 6, 8 and 9 are sectional views. FIG. 6 is a sectional view taken along line VI-VI in FIG. 5. FIG. 8 is a sectional view taken along line VIII-VIII in FIG. 7. FIG. 10 is an enlarged schematic view showing a portion of FIG. 9.

First, a support substrate 1 is prepared. For preparation of the support substrate 1, an insulating substrate, such as a silicon substrate, a glass epoxy substrate, or a ceramic substrate is used, for example. The support substrate 1 is rectangular in plan view, for example.

Next, a second conductor layer 32 is formed on the support substrate 1. To form the second conductor layer 32, a plating layer is formed on the entire upper surface of the support substrate 1, and the plating layer is patterned by photolithography, as shown in FIGS. 5 and 6. The material of the plating layer is Cu or a Cu alloy, for example. The patterned plating layer forms the second conductor layer 32 (a plurality of second conductor portions 321), as shown in FIGS. 5 and 6. In the present embodiment, the patterned plating layer also forms the connecting portion 34 connecting to the second conductor layer 32, as shown in FIG. 5.

Next, a resin composite body 2 is formed on the support substrate 1 to cover the second conductor layer 32. The resin composite body 2 is made of a resin material 20 containing a plurality of magnetic particles 21. In the resin composite body 2 formed on the support substrate 1, all of the magnetic particles 21 are the first particles 22 and include first cores 221 made of metallic magnetic powder and insulating coating films 222 that are the oxide of the metallic magnetic powder. That is, in this state, the surfaces of all magnetic particles 21 are covered with insulating coating films.

Next, as shown in FIGS. 7 and 8, a plurality of vias 331 (conducting portion 33) are formed. A known method may be used to form the vias 331. Each of the formed vias 331 penetrates the resin composite body 2 in the z direction to connect to the second conductor layer 32. In the present embodiment, as shown in FIG. 7, a portion of a connecting portion 34 is also formed in forming the vias 331 (conducting portion 33).

Next, a first conductor layer 31 is formed on the upper surface of the resin composite body 2. To form the first conductor layer 31, the upper surface of the resin composite body 2 is irradiated with a laser light at an area in which the first conductor layer 31 is to be formed. In the resin composite body 2 irradiated with a laser light, the resin material 20 melts. Some of the molten resin material 20 may disappear. The portion recessed from the upper surface of the resin composite body 2 in FIGS. 9 and 10 is the area irradiated with a laser light. During this process, as shown in FIG. 10, a plurality of magnetic particles 21 that have been dispersed in the molten resin material 20 appear to the surface of the resin composite body 2. The insulating coating film 222 on the surface of each of the appearing magnetic particles 21 is partially or entirely destroyed by the laser light irradiation. In this way, each of the appearing magnetic particles 21 becomes a second particle 23, as shown in FIG. 10. That is, a plurality of second particles 23 are formed in the area irradiated with a laser light. Thereafter, electroless plating is performed, using the magnetic particles 21 appearing to the upper surface of the resin composite body 2 (i.e., second particles 23) as a seed. By this process, a plating layer that is in contact with the second particles 23 is deposited. The material of the plating layer is Cu or a Cu alloy, for example. The deposited plating layer forms the first conductor layer 31 (a plurality of first conductor portions 311). In the present embodiment, the deposited plating layer also forms the connecting portion 34 connecting to the first conductor layer 31, and a pair of terminals 35.

The circuit component A1 shown in FIGS. 1 to 4 is manufactured through the above-described steps. The above-described manufacturing method is merely an example, and the present disclosure is not limited to this. The method can be varied as follows. In the above-described manufacturing method, the second conductor layer 32 is formed by patterning the plating layer formed on the entire upper surface of the support substrate 1. However, the second conductor layer 32 may be formed by other methods. For example, a resin layer of the same material as the resin composite body 2 may be formed on the upper surface of the support substrate 1, and the resin layer may be irradiated with a laser light to make the second particles 23 appear. Then, electroless plating using the appearing second particles 23 as a seed may be performed to form the second conductor layer 32. Also, the first conductor layer 31 and the conducting portion 33 may be formed collectively. For example, immediately after the resin composite body 2 is formed, i.e., before the conducting portion 33 is formed, laser processing may be performed to the areas at which the first conductor layer 31 and the conducting portion 33 are to be formed. Thereafter, electroless plating for the first conductor layer 31 and the conducting portion 33 may be performed. With this method, the first conductor layer 31 and the conducting portion 33 can be formed collectively.

Next, a semiconductor device B1 that uses the circuit component A1 is described below with reference to FIG. 11. As shown in FIG. 11, the semiconductor device B1 includes the circuit component A1, a transistor Tr, a capacitor C, a circuit board 91, and a sealing member 92. FIG. 11 is a front view of the semiconductor device B1. In FIG. 11, the sealing member 92 is shown by imaginary lines (two-dot chain lines).

As shown in FIG. 11, the semiconductor device B1 has a BGA (Ball Grid Array) package structure, for example. Unlike the example shown in FIG. 11, the semiconductor device B1 may have a package structure other than the BGA type. The semiconductor device B1 is, for example, a power supply module incorporating the transistor Tr.

The circuit board 91 is a printed board, for example. The circuit board 91 supports the circuit component A1, the transistor Tr, the capacitor C and the sealing member 92. The circuit board 91 is formed with a conductor pattern (not shown), through which elements such as the circuit component A1, the transistor Tr, and the capacitor C are electrically connected as appropriate. In the state in which the circuit component A1 is mounted on the circuit board 91, the surface formed with the terminals 35 faces the circuit board 91, with the terminals 35 bonded to the conductor pattern. In the example in which the semiconductor device B1 has the BGA package structure, the circuit board 91 is formed with a plurality of small ball-shaped electrodes 911 on the surface (lower surface) opposite, in the z direction, to the surface (upper surface) on which the elements such as the circuit component A1, the transistor Tr, the capacitor C, and the sealing member 92 are disposed.

The sealing member 92 is formed on the circuit board 91 to cover the elements such as the circuit component A1, the transistor Tr, and the capacitor C. The material of the sealing member 92 is an insulating resin, which may be epoxy resin in one example.

The transistor Tr is a MOSFET (Metal-Oxide-Semiconductor Field-Effect Transistor), an IGBT (Insulated Gate Bipolar Transistor), or a HEMT (High Electron Mobility Transistor), for example. The material of the transistor Tr is a semiconductor material such as Si, Sic, or GaN.

Advantages of the circuit component A1 and the semiconductor device B1 are described below.

The circuit component A1 includes the resin composite body 2 and the conductor 3. The resin composite body 2 contains a plurality of magnetic particles 21 in the resin material 20. The plurality of magnetic particles 21 are dispersed in the resin material 20. With such a configuration, part of the magnetic flux generated due to the current flowing in the conductor 3 concentrates on the plurality of magnetic particles 21, so that leakage of the magnetic flux reduces. Thus, the inductance value of the circuit component A1 is improved. Further, each of the magnetic particles 21 is smaller than bar-shaped or annular magnetic cores, so that the loop area of the eddy current can be made smaller. That is, the use of a plurality of magnetic particles 21 reduces eddy current loss and iron loss. In particular, since the eddy current loss is proportional to the square of the frequency of the current flowing the conductor 3, the higher the frequency of the current flowing in the conductor 3, the more effective the reduction of eddy current loss is. Thus, the circuit component A1 achieves both improvement of the inductance value and reduction of iron loss. Moreover, since the magnetic flux leakage is reduced, adverse effect of the magnetic flux leakage on other equipment can be reduced.

In the circuit component A1, the plurality of magnetic particles 21 include a plurality of first particles 22. The first particles 22 are insulating and dispersed in the resin material 20 in the resin composite body 2. When at least a portion of the conductor 3 (the first conductor layer 31 in the present embodiment) is to be formed by electroless plating, if all magnetic particles 21 are conductive (i.e., with no first particles 22 included), plating may grow on seeds or magnetic particles 21 appearing on the surface of the resin composite body 2. In such a case, selective formation of the conductor is not possible. In the circuit component A1, on the other hand, the first particles 22 dispersed in the resin material 20 in the resin composite body 2 are insulating. Thus, when the first particles 22 have appeared on the surface of the resin composite body 2, plating will not grow on such first particles 22. Thus, selective formation of the conductor 3 is possible in the circuit component A1.

In the circuit component A1, the plurality of magnetic particles 21 include a plurality of second particles 23. The second particles 23 are in contact with the conductor 3 (e.g., the first conductor layer 31). Each second particle 23 includes a second core 231, and the second core 231 forms at least a portion of the surface of the second particle 23. The second cores 231 are made of metallic magnetic powder having the same composition as the metallic magnetic powder of the first cores 221. Each second particle 23 is a magnetic particle 21 that has subjected to laser light irradiation and formed by partially or entirely destroying the insulating coating film 232 covering the surface of the second core 231 by laser light irradiation. Examples of a method for forming a conductor on the surface of a resin material include LDS (Laser Direct Structuring). In LDS, metal cores are formed on the surface of a resin material containing an LDS additive by using a laser, and a conductor is selectively formed only at the laser irradiated areas by e.g., electroless plating using the metal cores as seeds. In this way, an LDS additive is needed in LDS. In the circuit component A1, on the other hand, metal cores are formed from some of magnetic particles (second particles 23), instead of an LDS additive. That is, in the circuit component A1, a portion of the conductor 3 (the first conductor layer 31 in the present embodiment) can be formed by a process similar to LDS without adding an LDS additive. Moreover, since a portion of the conductor 3 can be formed by a process similar to LDS, a fine conductor pattern (each first conductor portion 311) can be formed. Thus, the circuit component A1 can be miniaturized.

In the circuit component A1, the insulating coating film 222 of each of the first particles 22 is formed of the oxide of the first core 221. According to such a configuration, the insulating coating film 222 can be formed on the surface of the first core 221 by thermally oxidizing the first core 221. That is, the insulating coating film 222 is formed by thermally oxidizing metallic magnetic powder forming the first core 221. Thus, in the circuit component A1, the insulating magnetic particles 21, i.e., the first particles 22 are easily formed.

In the circuit component A1, the conductor 3 is wound into a toroidal shape. With such a configuration, the magnetic flux generated by the current flowing in each of the first conductor portion 311 of the first conductor layer 31 and the magnetic flux generated by the current flowing in each of the second conductor portion 321 of the second conductor layer 32 point in the same direction in the area sandwiched between the first conductor layer 31 and the second conductor layer 32 in the z direction and point in opposite directions in the areas outside the first conductor layer 31 and the second conductor layer 32 (i.e., above the first conductor layer 31 and below the second conductor layer 32) in the z direction. Thus, the circuit component A1 can reduce magnetic flux leakage while improving the inductance value.

The semiconductor device B1 includes the circuit component A1 and the transistor Tr. As described above, the circuit component A1 reduces magnetic flux leakage. Thus, the semiconductor device B1 can reduce the adverse effect of magnetic flux leakage from circuit component A1 on the operation of transistor Tr.

In the semiconductor device B1, the transistor Tr and the circuit component A1 are covered with the sealing member 92. With such a configuration, the transistor Tr and the circuit component A1 are packaged together as one unit. Thus, the semiconductor device B1 can be miniaturized by miniaturizing the circuit component A1.

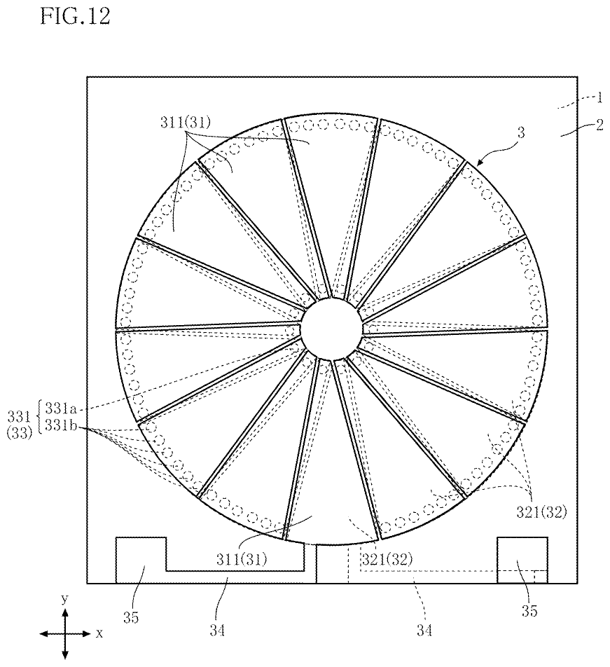

In the first embodiment, the shapes of the first conductor portions 311 (the first conductor layer 31) and the second conductor portions 321 (the second conductor layer 32) are not limited to the above-described examples. For example, the configuration shown in FIG. 12 may be employed. FIG. 12 is a plan view of a circuit component according to a variation. In the variation shown in FIG. 12, as compared with the circuit component A1, each of the first conductor portions 311 and each of the second conductor portions 321 are inclined in plan view with respect to the radial direction of the conductor 3. Such a configuration increases the area in which each of the first conductor portions 311 overlaps with a relevant one of the second conductor portions 321 in plan view. Thus, a wider area for forming the vias 331 is secured, making it possible to provide a larger number of vias 331. Thus, the example shown in FIG. 12 achieves better electric conduction between the first conductor layer 31 and the second conductor layer 32 through the vias 331 (conducting portion 33). Moreover, as will be understood from the comparison with FIG. 2, in the circuit component shown in FIG. 12, each inner via 331a can be further offset radially inward of the conductor 3, whereby each first conductor portion 311 and each second conductor portion 321 can be further extended radially inward of the conductor 3. As a result, the cross-sectional area of the magnetic path can be enlarged, and the inductance value can be increased. Thus, the variation shown in FIG. 12 can improve the inductance value over the circuit component A1.

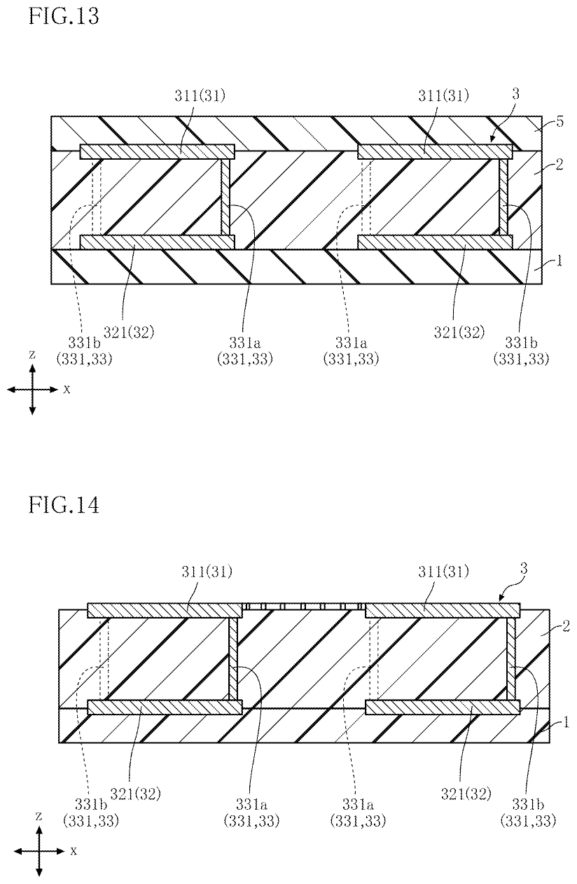

In the first embodiment, a resin member may be formed on top of the resin composite body 2 (i.e., on the side opposite, in the z direction, from the side on which support substrate 1 is disposed). FIG. 13 is a sectional view showing a circuit component according to such a variation and corresponds to the sectional view of FIG. 3. In the variation shown in FIG. 13, a resin member 5 is formed on the resin composite body 2 to cover the first conductor layer 31. The resin member 5 may be made of the same material as the resin composite body 2 or may be made of other resin materials (e.g., a resin material in which no magnetic particles 21 are dispersed or a resin material in which magnetic particles different from the magnetic particles 21 are dispersed). Also, a resin member 5 may be used instead of the support substrate 1, so that resin members 5 are formed on both the upper surface and the lower surface of the resin composite body 2. In particular, since the resin member 5 formed on the upper side (or on the upper and lower sides) of the resin composite body 2 does not need to be formed with a conductor 3, a resin material that does not contain an LDS additive (but may contain oxide-based magnetic particles such as ferrite dispersed therein) may be used for the resin member 5.

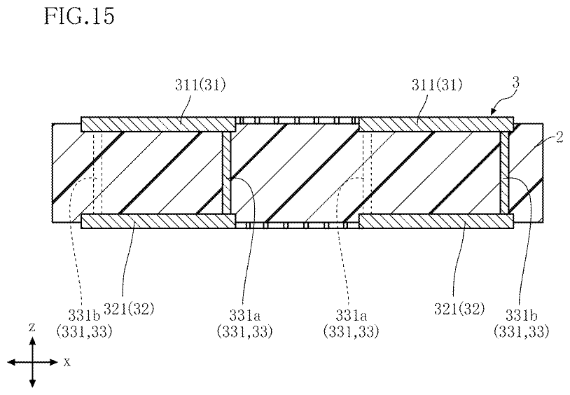

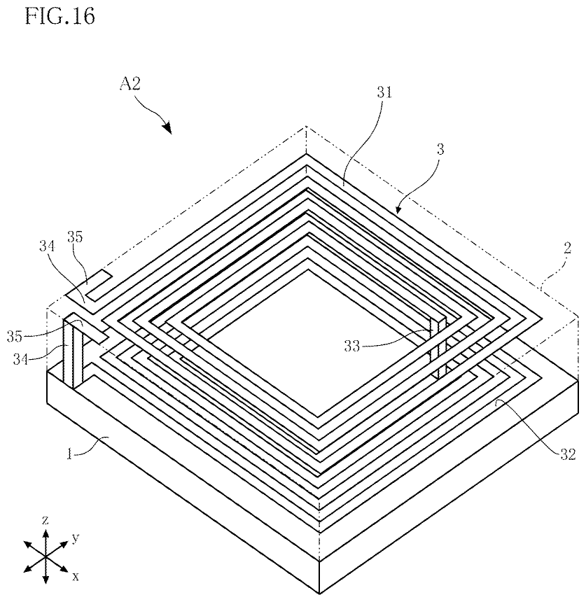

In the first embodiment, the support substrate 1 may be made of the same material as the resin composite body 2. That is, the support substrate 1 may not be an insulating substrate but may be made of a resin material 20 in which a plurality of magnetic particles 21 are dispersed. FIG. 14 is a sectional view showing a circuit component according to such a variation and corresponds to the sectional view of FIG. 3. In the variation shown in FIG. 14, the second conductor layer 32 can be formed by irradiating the support substrate 1 with a laser light to make the second particles 23 appear on the surface of the support substrate 1 and then performing electroless plating using the appearing second particles 23 as a seed. That is, in the present variation, the second conductor layer 32 can be formed in the same manner as the first conductor layer 31.

In the first embodiment, the circuit component A1 may not include the support substrate 1. FIG. 15 is a sectional view showing a circuit component according to such a variation and corresponds to the sectional view of FIG. 3. In the variation shown in FIG. 15, each surface of the resin composite body 2 in the z direction is irradiated with a laser light to make the second particles 23 appear. The first conductor layer 31 and the second conductor layer 32 can be formed by subsequently performing electroless plating using the appearing second particles 23 as a seed. The formation of a plurality of vias 331 (conducting portion 33) may be performed before the formation of the first conductor layer 31 and the second conductor layer 32 (i.e., before the laser irradiation) or may be performed after the formation of the first conductor layer 31 and the second conductor layer 32. Alternatively, the formation of the vias may be performed together with the formation of the first conductor layer 31 or the formation of the second conductor layer 32.

In the first embodiment, to improve the formation accuracy in forming a portion (e.g., the first conductor layer 31) of the conductor 3 by laser light irradiation and electroless plating, the above-described LDS additive may be added to the resin material 20 of the resin composite body 2, in addition to the magnetic particles 21.

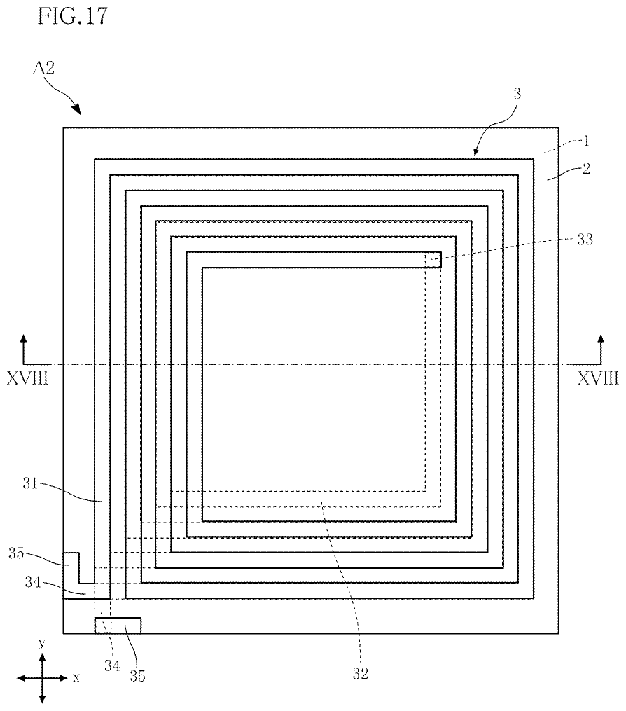

A circuit component A2 according to a second embodiment is described below with reference to FIGS. 16 to 18. As shown in FIGS. 16 to 18, the circuit component A2 differs from the circuit component A1 in configuration of the conductor 3.

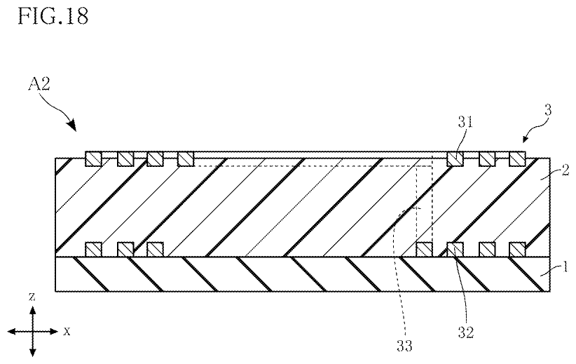

FIG. 16 is a perspective view of the circuit component A2. In FIG. 16, the resin composite body 2 is shown by imaginary lines (two-dot chain lines). FIG. 17 is a plan view of the circuit component A2. FIG. 18 is a sectional view taken along line XVIII-XVIII in FIG. 17.

As shown in FIGS. 16 and 17, the conductor 3 of the present embodiment includes a first conductor layer 31 and a second conductor layer 32 each wound into a planar spiral shape. The number of turns of each of the first conductor layer 31 and the second conductor layer 32 is not limited.

In the circuit component A2, the current inputted to one of the terminals 35 is inputted to the first conductor layer 31 through the connecting portion 34 connecting to that terminal 35. The current inputted to the first conductor layer 31 flows through the first conductor layer 31 to be inputted to the second conductor layer 32 through the conducting portion 33. The current inputted to the second conductor layer 32 flows through the second conductor layer 32 and outputted from the other terminal 35 through the connecting portion 34 connecting to the second conductor layer 32.

As with the circuit component A1, the circuit component A2 also includes a resin composite body 2 and a conductor 3. Thus, as with the circuit component A1, the circuit component A2 can improve the inductance value, because part of the magnetic flux generated due to the current flowing in the conductor 3 concentrates on the plurality of magnetic particles 21. Further, the use of a plurality of magnetic particles 21 reduces eddy current loss and iron loss. Thus, as with the circuit component A1, the circuit component A2 achieves both improvement of the inductance value and reduction of iron loss.

The circuit component A2 have the same advantages as the circuit component A1 due to its common configuration with the circuit component A1. The circuit component A2 may be used in place of the circuit component A1 in the semiconductor device B1.

The circuit component A2 can be configured in the same manner as each of the above-described variations of the circuit component A1. For example, in the circuit component A2 again, a resin member 5 may be formed on the upper surface of the resin composite body 2, the support substrate 1 may be made of the same material as the resin composite body 2, or the support substrate 1 may be dispensed with.

The first embodiment and the second embodiment show examples in which the conductor 3 forms an inductor. However, the present disclosure is not limited to this, and the conductor 3 may form a transformer or an LC filter. For a transformer, the conductor 3 forms two windings. The two windings are arranged to be magnetically coupled to each other. For an LC filter, the conductor 3 forms an inductor portion and a capacitor portion.

The circuit component and the semiconductor device according to the present disclosure are not limited to the foregoing embodiments. The specific configuration of each part of the circuit component and the semiconductor device according to the present disclosure may be varied in design in many ways. For example, the circuit component and the semiconductor device according to the present disclosure include embodiments described in the following clauses.

Clause 1.

A circuit component comprising:
a resin composite body including a resin material containing a plurality of magnetic particles; and
a conductor formed on a surface of the resin composite body,
wherein the plurality of magnetic particles are dispersed in the resin material.

Clause 2.

The circuit component according to clause 1, wherein the plurality of magnetic particles include a first particle that is insulating.

Clause 3.

The circuit component according to clause 2, wherein the first particle includes a first core made of metallic magnetic powder and an insulating coating film covering an entire surface of the first core.

Clause 4.

The circuit component according to clause 3, wherein the insulating coating film is made of an oxide of the first core.

Clause 5.

The circuit component according to clause 3 or 4, wherein the plurality of magnetic particles further include a second particle that is in contact with the conductor,
the second particle includes a second core made of metallic magnetic powder having a same composition as the metallic magnetic powder of the first core, and
the second particle has a surface at least a part of which is formed by the second core.

Clause 6.

The circuit component according to any one of clauses 1 to 5, wherein a material of the conductor includes Cu.

Clause 7.

The circuit component according to any one of clauses 1 to 6, wherein the plurality of magnetic particles contain one of Fe, Ni and Co.

Clause 8.

The circuit component according to any one of clauses 1 to 7, wherein the resin composite body has a relative magnetic permeability of 10 or greater.

Clause 9.

The circuit component according to any one of clauses 1 to 8, wherein the conductor forms an inductor.

Clause 10.

The circuit component according to clause 9, wherein the inductor has a self-inductance of 10 nH or greater.

Clause 11.

The circuit component according to any one of clauses 1 to 10, wherein the conductor includes a first conductor layer, a second conductor layer, and a conducting portion,
the first conductor layer and the second conductor layer face each other with the resin composite body interposed therebetween, and
the conducting portion connects the first conductor layer and the second conductor layer to each other.

Clause 12.

The circuit component according to clause 11, wherein the first conductor layer is divided into a plurality of first conductor areas,
the second conductor layer is divided into a plurality of second conductor areas,
the conducting portion includes a plurality of vias each of which electrically connects one of the plurality of first conductor areas and one of the plurality of second conductor areas, and
each of the plurality of vias is formed at a portion where one of the plurality of first conductor areas and one of the plurality of second conductor areas overlap with each other as viewed in a direction perpendicular to the first conductor layer and the second conductor layer.

Clause 13.

A semiconductor device comprising:
a circuit component as set forth in any one of clauses 1 to 12; and
a transistor electrically connected to the circuit component.

Clause 14.

The semiconductor device according to clause 13, further comprising a sealing member made of a resin,
wherein the sealing member covers the circuit component and the transistor.

Clause 15.

The semiconductor device according to clause 13 or 14, wherein the transistor is one of a MOSFET, an IGBT, or a HEMT.

Clause 16.

The semiconductor device according to any one of clauses 13 to 15, wherein a material of the transistor includes one of SiC, Si, or GaN.

REFERENCE NUMERALS

| | |
|---|---|
| A1, A2: Circuit component | 1: Support substrate |
| 2: Resin composite body | 20: Resin material |
| 21: Magnetic particles | 22: First particles |
| 221: First core | 222: Insulating coating film |
| 23: Second particles | 231: Second core |
| 232: Insulating coating film | 3: Conductor |
| 31: First conductor layer | 311: First conductor portion |
| 32: Second conductor layer | 321: Second conductor portion |
| 33: Conducting portion | 331: Vias |
| 331a: Inner vias | 331b: Outer vias |
| 34: Connecting portion | 35: Terminals |
| 5: Resin member | B1: Semiconductor device |
| C: Capacitor | Tr: Transistor |
| 91: Circuit board | 92: Sealing member |
| 911: Electrode | |

1. A circuit component comprising:
a resin composite body including a resin material containing a plurality of magnetic particles; and
a conductor formed on a surface of the resin composite body,
wherein the plurality of magnetic particles are dispersed in the resin material.

2. The circuit component according to claim 1, wherein the plurality of magnetic particles include a first particle that is insulating.

3. The circuit component according to claim 2, wherein the first particle includes a first core made of metallic magnetic powder and an insulating coating film covering an entire surface of the first core.

4. The circuit component according to claim 3, wherein the insulating coating film is made of an oxide of the first core.

5. The circuit component according to claim 3, wherein the plurality of magnetic particles further include a second particle that is in contact with the conductor,
the second particle includes a second core made of metallic magnetic powder having a same composition as the metallic magnetic powder of the first core, and
the second particle has a surface at least a part of which is formed by the second core.

6. The circuit component according to claim 1, wherein a material of the conductor includes Cu.

7. The circuit component according to claim 1, wherein the plurality of magnetic particles contain one of Fe, Ni and Co.

8. The circuit component according to claim 1, wherein the resin composite body has a relative magnetic permeability of 10 or greater.

9. The circuit component according to claim 1, wherein the conductor forms an inductor.

10. The circuit component according to claim 9, wherein the inductor has a self-inductance of 10 nH or greater.

11. The circuit component according to claim 1, wherein the conductor includes a first conductor layer, a second conductor layer, and a conducting portion,
the first conductor layer and the second conductor layer face each other with the resin composite body interposed therebetween, and
the conducting portion connects the first conductor layer and the second conductor layer to each other.

12. The circuit component according to claim 11, wherein the first conductor layer is divided into a plurality of first conductor areas,
the second conductor layer is divided into a plurality of second conductor areas,
the conducting portion includes a plurality of vias each of which electrically connects one of the plurality of first conductor areas and one of the plurality of second conductor areas, and
each of the plurality of vias is formed at a portion where one of the plurality of first conductor areas and one of the plurality of second conductor areas overlap with each other as viewed in a direction perpendicular to the first conductor layer and the second conductor layer.

13. A semiconductor device comprising:
a circuit component as set forth in claim 1; and
a transistor electrically connected to the circuit component.

14. The semiconductor device according to claim 13, further comprising a sealing member made of a resin,
wherein the sealing member covers the circuit component and the transistor.

15. The semiconductor device according to claim 13, wherein the transistor is one of a MOSFET, an IGBT, or a HEMT.

16. The semiconductor device according to claim 13, wherein a material of the transistor includes one of SiC, Si, or GaN.
